(19) United States
(12) Patent Application Publication
(10) Pub. No.: US 2019/0293242 A1
(43) Pub. Date: Sep. 26, 2019

(54) LED MODULE AND LED LAMP INCLUDING THE SAME

(71) Applicant: Samsung Electronics Co., Ltd., Suwon-si (KR)

(72) Inventors: Mi Hyae Park, Suwon-si (KR); Ho Sun Paek, Suwon-si (KR); Jae Sung You, Osan-si (KR); Chul Soo Yoon, Hwaseong-si (KR); Young Mook Lim, Daejeon (KR)

(73) Assignee: Samsung Electronics Co., Ltd., Suwon-si (KR)

(21) Appl. No.: 16/180,271

(22) Filed: Nov. 5, 2018

(30) Foreign Application Priority Data
Mar. 22, 2018 (KR) 10-2018-0033410

(51) Int. Cl. F21K 9/232; F21V 23/06; H01L 25/075; H01L 23/538; H01L 33/50; H01L 33/56; H01L 33/62

(52) U.S. Cl. CPC F21K 9/232; F21V 23/06; H01L 25/0753; F21Y 2115/10; H01L 33/504; H01L 33/56; H01L 33/62; H01L 23/5387

(57) ABSTRACT

An LED module includes a flexible substrate having a first surface on which a circuit pattern is disposed and a second surface opposing the first surface, and having a light transmittance of 80% or more; a plurality of LED chips mounted on the first surface of the flexible substrate, and electrically connected to the circuit pattern; first and second connection terminals disposed at both ends of the flexible substrate, and connected to the circuit pattern; and a wavelength converter covering the plurality of LED chips, and surrounding the flexible substrate.

### CROSS-REFERENCE TO RELATED APPLICATION

This application claims benefit of priority to Korean Patent Application No. 10-2018-0033410 filed on Mar. 22, 2018 in the Korean Intellectual Property Office, the disclosure of which may be incorporated herein by reference in its entirety.

### BACKGROUND

### 1. Field

The present inventive concepts relate to a light emitting diode (LED) module and an LED lamp including the same.

### 2. Description of Related Art

In general, incandescent lamps or fluorescent lamps are commonly used as indoor or outdoor lighting lamps. Such incandescent lamps or fluorescent lamps have a relatively short lifespan and therefore frequently have to be replaced.

In order to solve such a problem, an illumination device using an LED having higher photoelectric conversion efficiency and/or an improved lifespan has come to prominence.

In addition, an LED device may offer various advantages, such as greater resistance to impacts, lower power consumption, a semi-permanent and versatile lighting effect, as compared to conventional bulb lamps or fluorescent lamps.

As such, as demand for the adoption of an LED in the field of illumination increases, various demands such as for processability and improved light distribution characteristics are also increasing.

### SUMMARY

An aspect of the present inventive concepts is to provide a filament-type LED module which may emit light having a high illumination level from a front surface as well as from a rear surface, and may be excellent in processability.

An aspect of the present inventive concepts is to provide an LED lamp employing a filament-type LED module which may emit light having a high illumination level from a front surface as well as from a rear surface, and may be excellent in processability.

According to an aspect of the present inventive concepts, an LED module includes a flexible substrate having a first surface on which a circuit pattern is disposed and a second surface opposing the first surface, and having a light transmittance of 80% or more; a plurality of LED chips on the first surface of the flexible substrate and electrically connected to the circuit pattern; first and second connection terminals at both ends of the flexible substrate, and connected to the circuit pattern; and a wavelength converter covering the plurality of LED chips and surrounding the flexible substrate.

According to an aspect of the present inventive concepts, an LED module includes a flexible substrate having first and second surfaces opposing each other, and having a light transmittance of 80% or more and a bar shape; a circuit pattern on at least the first surface of the flexible substrate; a plurality of LED chips on the first surface of the flexible substrate in the longitudinal direction of the flexible substrate and electrically connected to the circuit pattern; first and second connection terminals at both ends of the flexible substrate and connected to the circuit pattern; and a wavelength converter including a transparent resin containing at least one wavelength converting material, and having a first wavelength converter on the first surface of the flexible substrate, and a second wavelength converter on the second surface of the flexible substrate.

According to an aspect of the present inventive concepts, an LED lamp includes a base; a lamp cover on the base, and having an internal space; and at least one LED module in the internal space of the lamp cover, wherein the at least one LED module comprises: a flexible substrate having a first surface on which a circuit pattern is disposed and a second surface opposing the first surface, and having a light transmittance of 80% or more; a plurality of LED chips on the first surface of the flexible substrate and electrically connected to the circuit pattern; first and second connection terminals at both ends of the flexible substrate and connected to the circuit pattern; and a wavelength converter covering the plurality of LED chips and surrounding the flexible substrate.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a side cross-sectional view illustrating a light emitting diode (LED) module according to some embodiments of the present inventive concepts,

FIG. 2 is a top plan view of an LED module illustrated in FIG. 1,

FIG. 3 is a cross-sectional view illustrating an LED chip that may be employed in an LED module illustrated in FIG. 1,

FIG. 4 is a cross-sectional view of an LED module illustrated in FIG. 1 taken along line I-I′,

FIG. 5 is a cross-sectional view illustrating an LED module according to some embodiments of the present inventive concepts,

FIG. 6 is a graph illustrating a light transmittance according to wavelength of a colorless polyimide employed in some embodiments,

FIG. 7 is a side cross-sectional view illustrating an LED module according to some embodiments of the present inventive concepts,

FIG. 8 is a graph illustrating improvement in amount of light of an LED module according to some embodiments,

FIG. 9 is a perspective view illustrating an LED lamp according to some embodiments of the present inventive concepts,

FIG. 10 is a top plan view illustrating an LED lamp illustrated in FIG. 9,

FIG. 11 is a front view illustrating an LED lamp according to some embodiments of the present inventive concepts, and

FIGS. 12 and 13 are perspective views illustrating LED lamps according to various embodiments of the present inventive concepts, respectively.

### DETAILED DESCRIPTION

Hereinafter, example embodiments of the present inventive concepts will be described with reference to the accompanying drawings.

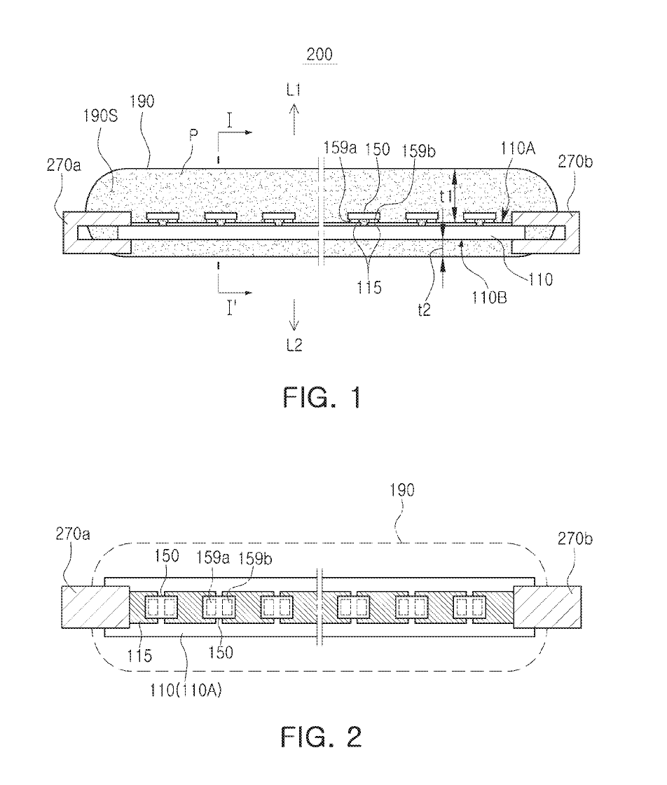

FIG. 1 is a side cross-sectional view illustrating a light emitting diode (LED) module according to some embodiments of the present inventive concepts, and FIG. 2 is a top plan view of an LED module illustrated in FIG. 1.

Referring to FIGS. 1 and 2, an LED module 200 according to some embodiments may include a flexible substrate 110 having a first surface 110A and a second surface 110B disposed opposing each other, a plurality of LED chips 150 mounted on the first surface 110A of the flexible substrate 110, first and second connection terminals 270a and 270b for applying a driving voltage, connected to the plurality of LED chips 150, and a wavelength converter 190 covering the plurality of LED chips 150, and surrounding the flexible substrate 110.

The flexible substrate 110 may include a circuit pattern 115 disposed on the first surface 110A. The plurality of LED chips 150 may be electrically connected to the circuit pattern 115. For example, the plurality of LED chips 150 may be connected to the circuit pattern 115 in a flip-chip bonding manner. For example, first and second electrodes 159a and 159b of the plurality of LED chips 150 may be connected to the circuit pattern 115 by a solder, for example.

The flexible substrate 110 employed in some embodiments may have a light transmittance of 80% or more, such that not only the flexible substrate 110 is processed into various shapes in a lamp to have flexibility, but also a light distribution of a rear surface is sufficiently ensured. In a specific example, the flexible substrate 110 may have a light transmittance of 90% or more.

In some embodiments, ‘a light distribution of a rear surface’ may be a term comparable to a light emission of a front surface indicating an amount of light emitted in a first direction, and may mean an amount of light (flux) emitted from the second surface 110B. The light transmittance may indicate a portion of a visible light band (for example, from 440 nm to 660 nm) or an entire visible light band including the same (for example, from 400 nm to 800 nm), and in fact, may evaluate as a light transmittance at 550 nm corresponding to an intermediate wavelength.

For example, the flexible substrate 110 may comprise a material selected from the group consisting of polyimide (PI), polyamide imide (PAI), polyethylene terephthalate (PET), polyethylene naphthalene (PEN) and silicone. In the case of silicone, it may be composed of a mixture of a polyorganosiloxane, a silicone resin, a crosslinking agent and a catalyst. In addition, a polymer resin such as epoxy, satisfying a condition that the light transmittance (80% or more) may be used.

A material constituting the flexible substrate 110 employed in some embodiments may satisfy the light transmittance condition of 80% or more, even when it is an example material. For example, since conventional aromatic polyimide has a lower light transmittance (for example, 70% or less) because it is colored like yellowish polyimide, a colorless polyimide having a higher light transmittance may be used to perform an additional process to satisfy a light transmittance condition in some embodiments. This will be described in detail with reference to FIG. 6.

As described above, since the flexible substrate 110 employed in some embodiments uses a flexible material having a light transmittance of 80% or more, the light distribution of the rear surface may be improved.

As illustrated in FIG. 2, a plurality of LED chips 150 may be arranged in a single row, and may be connected in series by the circuit pattern 115. First and second connection terminals 270a and 270b may be disposed at both ends of the flexible substrate 110 to be connected to the circuit pattern 115. In other embodiments, the plurality of LED chips 150 may be arranged in a plurality of rows, and may be partially connected in parallel. For example, when arranged in a plurality of rows, they may be connected in series at each row, and the plurality of rows may be connected to the first and second connection terminals 270a and 270b in parallel.

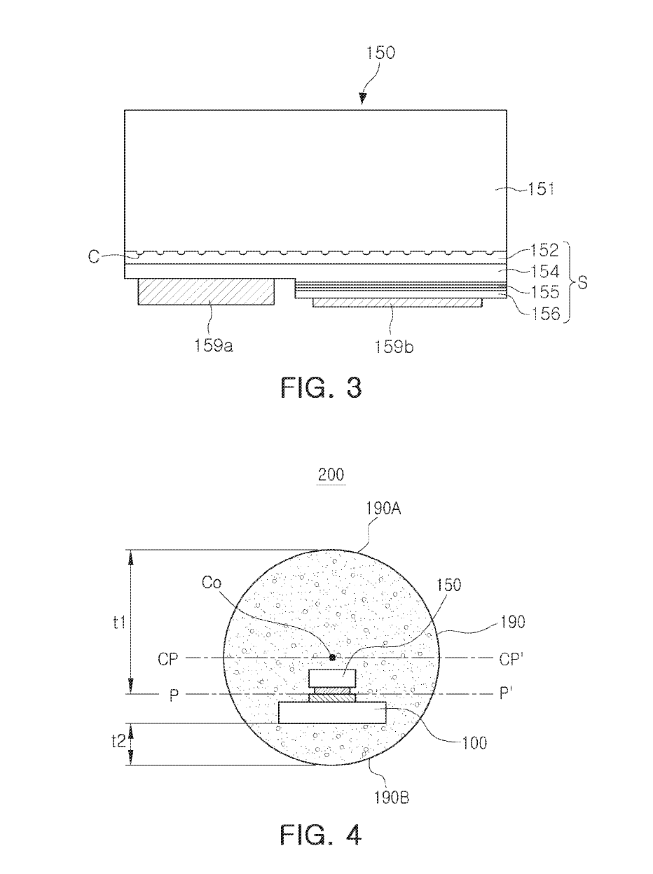

The LED chip 150 employed in some embodiments may be an LED having the flip-chip structure as described above. FIG. 3 is a cross-sectional view illustrating an LED chip that may be employed in an LED module illustrated in FIG. 1.

Referring to FIG. 3, a LED chip 150 may include a light-transmitting substrate 151, and a first conductivity type semiconductor layer 154, an active layer 155 and/or a second conductivity type semiconductor layer 156 sequentially disposed on the substrate 151. A buffer layer 152 may be disposed between the substrate 151 and the first conductivity type semiconductor layer 154.

The substrate 151 may be an insulation substrate such as sapphire. The present inventive concepts may be not limited thereto. The substrate 151 may be a conductive substrate or a semiconductor substrate in addition to the insulation substrate. For example, the substrate 151 may be SiC, Si, MgAl₂O₄, MgO, LiAlO₂, LiGaO₂, or GaN in addition to the sapphire. An unevenness C may be formed on an upper surface of the substrate 151. The unevenness C may improve quality of the grown single crystal, while improving light extraction efficiency.

The buffer layer 152 may be InxAlyGa1-x-yN (0≤X≤1, 0≤Y≤1). For example, the buffer layer 152 may be GaN, AlN, AlGaN, or InGaN. It may be used by combining a plurality of layers, or by gradually changing a composition.

The first conductivity type semiconductor layer 154 may be a nitride semiconductor that satisfies n-type InxAlyGa1-x-yN (0≤x<1, 0≤y<1, 0≤x+y<1), and the n-type impurity may be Si. For example, the first conductivity type semiconductor layer 154 may include n-type GaN. The second conductivity type semiconductor layer 156 may be a nitride semiconductor layer that satisfies a p-type InxAlyGa1-x-yN (0≤x<1, 0≤y<1, 0≤x+y<1), the p-type impurity may be Mg. For example, the second conductivity type semiconductor layer 156 may have a single-layer structure, or have a multi-layer structure having different compositions, as in the present example. The active layer 155 may be a multiple quantum well (MQW) structure in which a quantum well layer and a quantum barrier layer are stacked in an alternative way. For example, the quantum well layer and the quantum barrier layer may be InxAlyGa1-x-yN (0≤x≤1, 0≤y≤1, 0≤x+y≤1) having different compositions. In a specific example, the quantum well layer may be InxGa1-xN (0<x≤1), and the quantum barrier layer may be GaN or AlGaN. Thicknesses of the quantum well layer and the quantum barrier layer may each be in the range of 1 nm to 50 nm. The active layer 155 is not limited to a multiple quantum well structure, and may be a single quantum well structure.

First and second electrodes 159a and 159b may be disposed on a mesa-etched region of the first conductivity type semiconductor layer 154, and on the second conductivity type semiconductor layer 156, respectively, to be coplanar. The first electrode 159a may include a material such as Ag, Ni, Al, Cr, Rh, Pd, Jr, Ru, Mg, Zn, Pt, Au, or the like, and may be adopted as a single layer or in the form of two or more layers, but not limited thereto. The second electrode 159b may be a transparent electrode such as a transparent conductive oxide or a transparent conductive nitride, or may include graphene, as needed. The second electrode 159b may include at least one of Al, Au, Cr, Ni, Ti, and Sn.

The wavelength converter 190 employed in some embodiments may include a wavelength converting material P such as a fluorescent material or a quantum dot, and a transparent resin 190S containing the same. The wavelength converting material P may convert a portion of light generated from the plurality of LED chips 150 into light of the converted wavelength. The wavelength converting material P may be composed of at least one wavelength converting material such that the finally emitted light is obtained as white light. For example, the wavelength converting material (P) may include at least one of a yellow fluorescent material, a green fluorescent material, and a red fluorescent material, when the wavelength converting material (P) includes two or more wavelength converting materials.

As illustrated in FIG. 1, the wavelength converter 190 may be formed to surround the flexible substrate 110 while covering the plurality of LED chips 150. Therefore, lights L1 and L2 emitted from the front and rear surfaces of the LED module 100 may all be converted into desired light through the wavelength converter 190.

The wavelength converter 190 may be described in detail with reference to FIG. 4. FIG. 4 is a cross-sectional view of an LED module illustrated in FIG. 1 taken along line I-I′.

Referring to FIG. 4, a wavelength converter 190 may include a first wavelength converter 190A disposed on a first surface 110A on which a plurality of LED chips 150 are disposed, and a second wavelength converter 190B disposed on the second surface 110B of the flexible substrate 110.

In some embodiments, the wavelength converter 190 may be formed such that a mounting surface P-P′ (or the first surface) of the flexible substrate 110 is disposed below a surface CP-CP′ passing through a center CO of the wavelength converter 190. In this structure, a surface area of the first wavelength converter 190A located on the front surface may be greater than a surface area of the second wavelength converter 190B located on the rear surface.

Such structure and arrangement may be used to adjust the amount of light from the front surface and the amount of light from the rear surface. As in some embodiments, thickness t1 of the first wavelength converter 190A may be adjusted by adjusting thickness t2 of the second wavelength converter 190B. In this way, when the thickness t2 of the second wavelength converter 190B is formed to be relatively thin, the total light amount L1 and the deviation in the front surface may be reduced, and the color tone of light emitted from the front and rear surfaces may be uniformly adjusted.

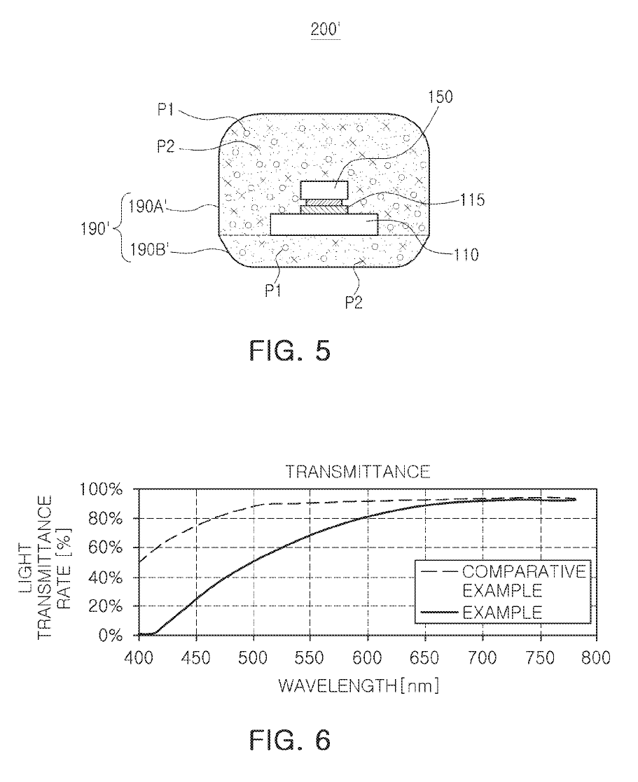

FIG. 5 is a cross-sectional view illustrating an LED module according to some embodiments of the present inventive concepts.

Referring to FIG. 5, similar to those previously described above, an LED module 200′ according to some embodiments may include a wavelength converter 190′ surrounding a flexible substrate 110 to cover a plurality of LED chips 150, and may have a structure having a substantially rectangular cross section. The cross-sectional structure of the wavelength converter 190′ may have various shapes.

The wavelength converter 190′ according to some embodiments may include a first wavelength converter 190A′ disposed on the front surface of the flexible substrate 110, and a second wavelength converter 190B′ disposed on the rear surface of the flexible substrate 110, and the first wavelength converter 190A′ and the second wavelength converter 190B′ may be formed, respectively, by separate processes.

As described above, since the first wavelength converter 190A′ and the second wavelength converter 190B′ are formed using other processes such as dispensing, different types of the wavelength converting materials P1 and P2, or different content ratios of the wavelength converting materials P1 and P2 may be included. Accordingly, by reducing scattering by the wavelength converting materials P1 and P2 in the second wavelength converter 190B′, compared to those in the first wavelength converter, an amount of light L2 from the rear surface may be increased, and an amount of light L1 from the front surface and a deviation may be reduced.

In some embodiments, a content ratio of the wavelength converting materials P1 and P2 of the first wavelength converter 190A′ may be greater than a content ratio of the wavelength converting materials P1 and P2 of the second wavelength converter 190B′.

The wavelength converter 190′ may include the first and second wavelength converting materials P1 and P2. In a case in which the plurality of LED chips 150 emit blue light, each of the first and second wavelength converting materials P1 and P2 may include at least one of a green fluorescent material and a red fluorescent material, or a yellow fluorescent material and a green fluorescent material and a red fluorescent material.

Similar to the previous embodiments, thickness t1 of the first wavelength converter 190A′ may be formed to be greater than thickness t2 of the second wavelength converter 190B′ to reduce a light amount L2 from the rear surface.

The material of the flexible substrate employed in some embodiments may be a polymer resin, a silicone composite resin or an epoxy resin, having a light transmittance of 80% or more, such that the light distribution of the rear surface is sufficiently ensured. For example, at least one of polyimide, polyamideimide, polyethylene terephthalate and polyethylene naphthalene may be used as the polymer resin. FIG. 6 is a graph illustrating a light transmittance according to wavelength of a colorless polyimide employed in some embodiments.

Referring to FIG. 6, conventional aromatic polyimide (Comparative Example) may have a relative low light transmittance in the visible light band (particularly, less than 70% at 550 nm or less) because it may be colored yellow. The colorless polyimide (Example) used in some embodiments may have a relative high light transmittance as a whole in a visible light zone, an average light transmittance of 80% or more, or a light transmittance of approximately 90%. When such polyimide is used to provide the flexible substrate 110, the light distribution of the rear surface may be improved.

In the aromatic polyimide according to Comparative Example, π electrons of benzene existing in a main chain of imide may be transferred to intermolecular bonding, and an energy level may be lowered to absorb a long wavelength band of a visible light zone. On the other hand, in a case of some embodiments, a functional structure including an element having a strong electronegativity may be introduced to restrict the electron transport, or a non-benzene cyclic structure may be introduced to decrease a density of π electrons, to provide a colorless polyimide having a relative high light transmittance.

As described above, the flexible substrate according to some embodiments may be made of a polymer resin or the like having a higher light transmittance of 80% or more, and moreover, 90% or more, thereby increasing the light distribution of the rear surface, to reduce a deviation between the light distribution of the front surface and the light distribution of the rear surface.

This light distribution characteristic may be influenced by other factors besides the transmittance rate of the flexible substrate. For example, the thickness and content ratio of the above-described wavelength converter may act as a factor for adjusting this.

The circuit pattern formed on the flexible substrate may also affect the light quantity and the light distribution characteristics. Such a circuit pattern may have reflectivity, which not only reduces the light distribution of the rear surface, but also absorbs light to cause light loss.

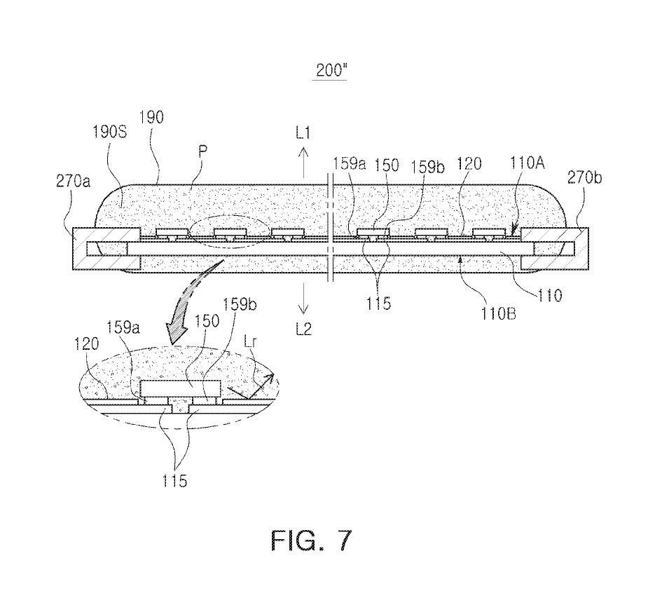

FIG. 7 is a side cross-sectional view illustrating an LED module according to some embodiments of the present inventive concepts.

Referring to FIG. 7, a semiconductor package 200″ according to some embodiments may be similar to the LED module 200 shown in FIGS. 1 and 2, except that a white coating layer may be formed on a surface of a circuit pattern. The description of components of some embodiments may be referred to the description of the same or similar components of the LED module 200 shown in FIGS. 1 and 2, unless otherwise specified.

An LED module 200′ according to some embodiments may include a flexible substrate 110 having a first surface 110A and a second surface 110B opposing each other, a plurality of light emitting diode (LED) chips 150 mounted on the first surface 110A of the flexible substrate 110, first and second connection terminals 270a and 270b for applying a driving voltage, connected to the plurality of LED chips 150, and a wavelength converter 190 covering the plurality of LED chips 150, and surrounding the flexible substrate 110.

A circuit pattern 115 may be disposed on the first surface 100A of the flexible substrate 110. For example, the circuit pattern 115 may be made of a metal such as copper (Cu). Such a circuit pattern 115 may be formed to have an appropriate area in consideration of a light distribution of a rear surface and heat radiation characteristics. For example, the area of the circuit pattern 115 may range from 1% to 60% of the area of the first surface 110A of the flexible substrate 110.

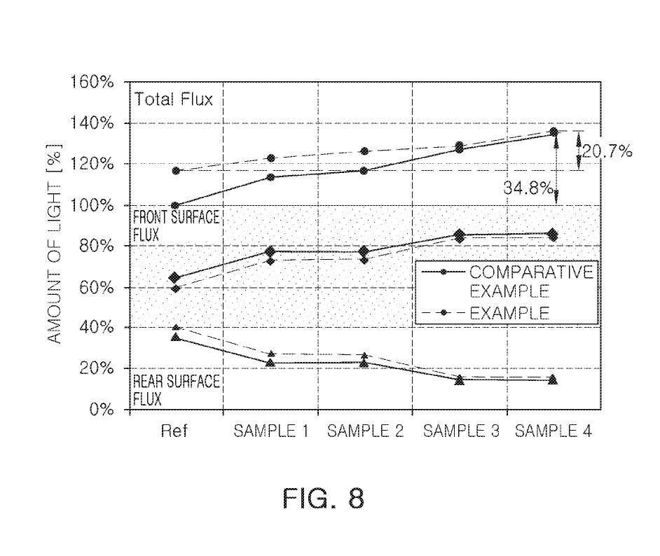

The LED module 200′ according to some embodiments may further include a white coating layer 120 disposed on the surface of the circuit pattern 115. As illustrated in FIG. 8, the white coating layer 120 may be disposed in an area of the circuit pattern 115 that may be not connected to the LED chip 150. For example, the white coating layer 120 may be a resin layer containing a white ceramic powder. The white ceramic powder may include at least one selected from TiO2, Al2O3, Nb2O5 and ZnO. In the LED module 200′, the circuit pattern 115 may absorb light to cause light loss. The white coating layer 120 may be used to reduce an occurrence of light loss due to the circuit pattern 115.

FIG. 8 is a graph illustrating improvement in amount of light of an LED module according to some embodiments.

FIG. 8 illustrates a change in amount of light according to an area and thickness of a white coating layer. The change in amount of light may be indicated by an amount of light emitted from a front surface and an amount of light emitted from a rear surface, as well as the total amount of light.

Each sample may have the same circuit pattern, and may form a white coating layer to cover a circuit pattern. An area and thickness of the coating layer were prepared as shown in Table 1 below.

TABLE 1

| | Coating Layer | | | | |
|---|---|---|---|---|---|
| | Ref. | Sample 1 | Sample 2 | Sample 3 | Sample 4 |
| Area | 0% | 36% | 36% | 75% | 75% |
| Thickness | 0 | 25 μm | 50 μm | 25 μm | 50 μm |

It can be seen that the amount of light from the front surface tends to increase more than the amount of light from the rear surface, as the area and thickness of the white coating layer increase. Further, it can be confirmed that, in Example using the colorless polyimide according to the present inventive concepts, a difference in the amount of light from the front surface and the amount of light from the rear surface was reduced, while increasing the amount of light from the rear surface, and the total amount of light was slightly increased, as compared with Comparative Example (solid line) using the conventional polyimide.

On the other hand, since the circuit pattern has higher thermal conductivity, it may be used as a heat dissipating means for emitting heat generated from a plurality of LED chips. Therefore, it may be necessary to limit the area of the circuit pattern from an optical viewpoint, and it may be necessary to ensure a least area from the viewpoint of heat dissipation. The formation area of the circuit pattern may be up to 60% of the area of the first surface of the flexible substrate.

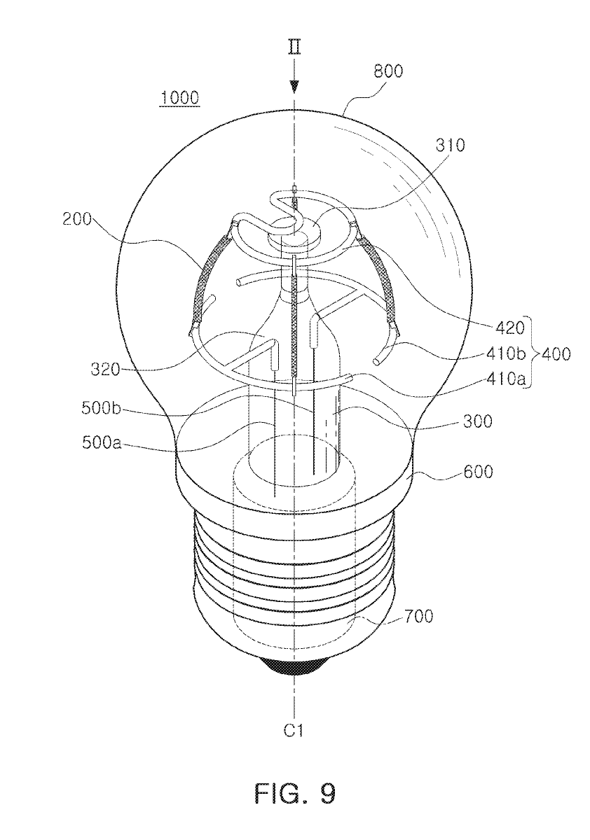

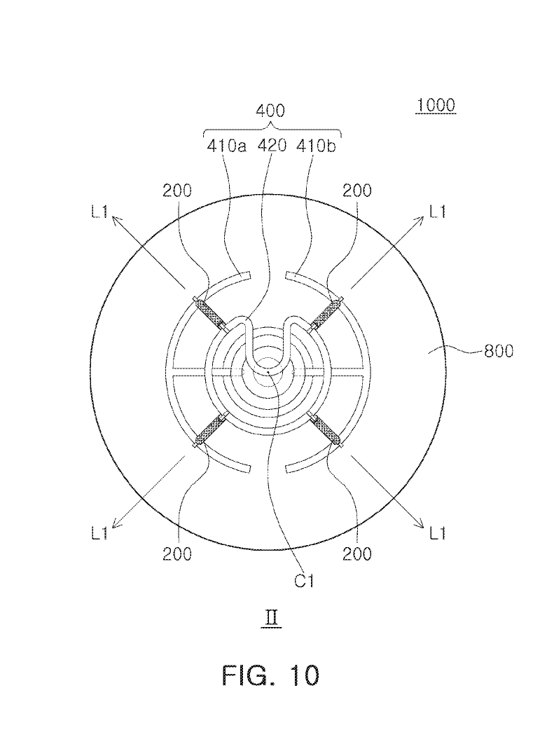

FIG. 9 is a perspective view illustrating an LED lamp according to some embodiments of the present inventive concepts, and FIG. 10 is a top plan view illustrating an LED lamp illustrated in FIG. 9, which is viewed from a direction II.

Referring to FIGS. 9 and 10, an LED lamp 1000 according to some embodiments may include a base 600 having a socket structure, a lamp cover 800 mounted on the base 600 and having an internal space, and a plurality of (for example, four) LED modules 200 disposed in the internal space of the lamp cover 800. In this case, the plurality of LED modules 200 may be LED modules 200′ according to other embodiments.

When a connection frame 420 or first and second electrode frames 410a and 410b are fixed each other, a main emitting surface (e.g., an upper surface) of the LED module 200 may be naturally directed toward the lamp cover 800, and a surface opposite thereto may be arranged to face a central portion C1.

The lamp cover 800 may be a transparent, a milky, a matte, or a colored bulb cover made of glass, hard glass, quartz glass or a light transmissive resin. The lamp cover 800 may be of various types. For example, this may be one of the existing bulb covers such as A-type, G-type, R-type, PAR-type, T-type, S-type, candle-type, P-type, PS-type, or BR-type.

The base 600 may be combined with the lamp cover 800 to form an outer shape of the LED lamp 1000, and may be formed with a socket structure such as E40-type, E27-type, E26-type, E14-type, GU-type, B22-type, BX-type, BA-type, EP-type, EX-type, GY-type, GX-type, GR-type, GZ-type, and G-type B40, to be replaced with the existing illumination device.

Power may be applied to the LED lamp 1000 through the base 600. A power supply unit 700 may be disposed in the internal space of the base 600, such that power applied through the base 600 is AC-DC converted, or a voltage is changed to supply to the LED module 200.

One end of a column 300 may be fixed to the central portion C1 of the base 600, and a frame 400 for fixing the LED module 200 to the column 300 may be disposed. The column 300 may cover an open area of the lamp cover 800, and may be welded through a high-temperature heat treatment to form a sealed internal space. Accordingly, the LED module 200 disposed in the internal space of the lamp cover 800 may be cut off from external moisture or the like.

The frame 400 may fix the LED module 200, and be made of a metal material to supply electric power. The frame 400 may include a connection frame 420 for connecting the plurality of LED modules 200, and the first and second electrode frames 410a and 410b for supplying electric power. A seating portion 310 for fixing the connection frame 420 may be formed at the other end of the column 300. The first and second electrode frames 410a and 410b may be fixed to a middle portion of the column 300 to support the plurality of LED modules 200 welded to the first and second electrode frames 410a and 410b. The first and second electrode frames 410a and 410b may be connected to the first and second electric wires 500a and 500b embedded in the column 300 such that power supplied from the power source unit 700 is applied.

The LED module 200 may be accommodated in a plurality in the internal space of the lamp cover 800. The LED module 200 may be manufactured in a shape similar to a filament of a conventional incandescent bulb. When power is applied, the LED module 200 may emit linear light like a filament, and may be also called an LED filament.

Referring to FIG. 10, an LED module 200 may be arranged radially such that a first surface of each LED module may be adjacent to a lamp cover 800. It may be arranged in a rotationally symmetrical manner with respect to a central portion C1 of a base 600, when viewed from an upper portion (II direction) of an LED lamp 1000. For example, in the internal space of the lamp cover 800, a main light emitting direction L1 of each LED module 200 may be arranged to be rotationally symmetrically arranged around a column 300 to face the lamp cover 800. In this arrangement, not only an emission of light from a front surface in the LED module 200 may be directly emitted through the lamp cover 800, but also an emission of light from a rear surface in the LED module 200 may contribute to the total output of light.

The frame and electrical connection structure employable in some embodiments are not limited thereto, and may be implemented in various structures. In particular, since the LED module 200 according to some embodiments includes a flexible substrate, the LED module 200 may be mounted in various shapes such as a bent shape to have a curved surface. Further, the LED module 200 according to some embodiments may be arranged to be oriented in various directions without being limited to a specific direction (the first surface faces the lamp cover) because a light distribution of a rear surface is enhanced.

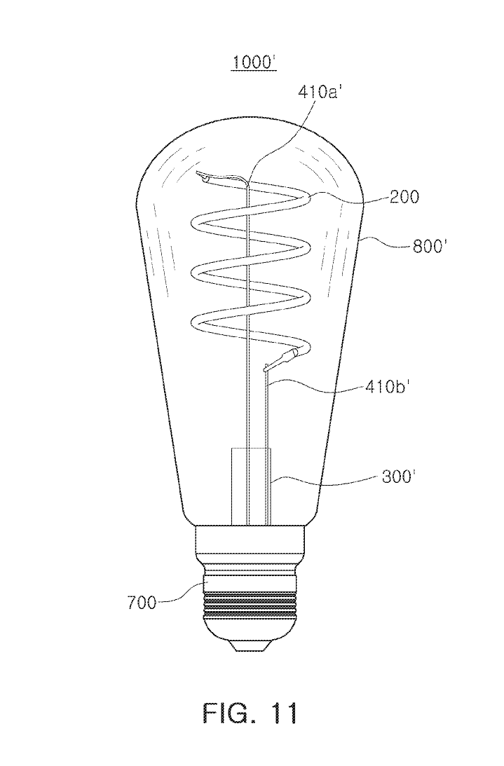

FIG. 11 is a front view illustrating an LED lamp according to some embodiments of the present inventive concepts.

Referring to FIG. 11, an LED lamp 1000′ according to some embodiments may be similar to an LED lamp 1000′ illustrated in FIG. 9 except for a point where one LED module may be bent in a plurality of regions, a structure of electrode frame. The description of the components of some embodiments may be referred to the description of the same or similar components of the LED lamp 1000 shown in FIGS. 9 and 10, unless otherwise specified.

A lamp cover 800′ may have a slightly elongated shape in an axial direction; unlike the lamp cover 800 employed in the previous embodiment. Both ends of an LED module 200 employed in some embodiments may be connected to first and second electrode frames 410a′ and 410b′, respectively, and the first electrode frame 410a′ disposed along the axial direction may be spirally wrapped. As such, since the LED module 200 includes a flexible substrate, it may be arranged in various bent shapes. Further, in another embodiment, a plurality of LED modules may be employed.

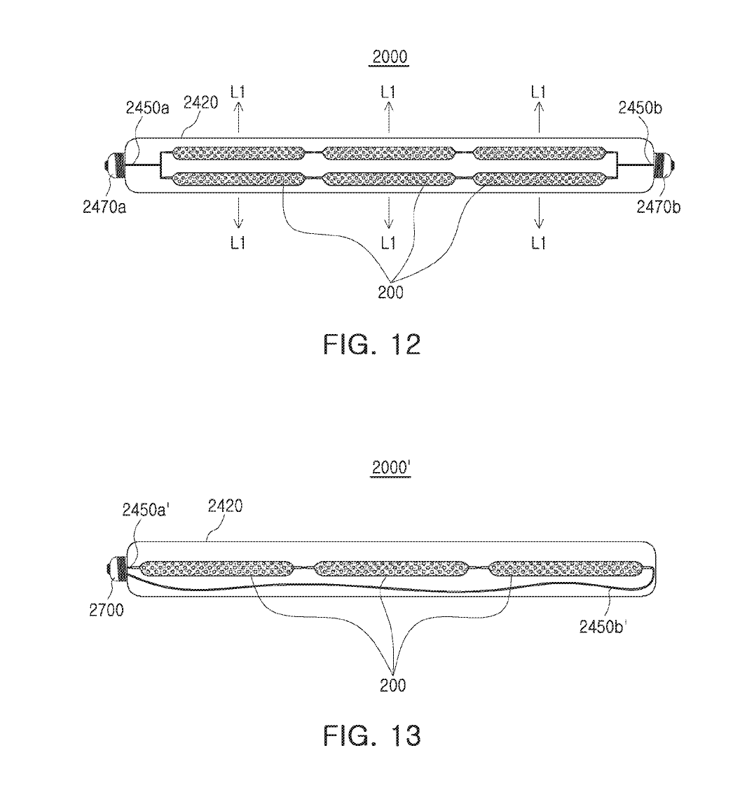

FIGS. 12 and 13 are perspective views illustrating LED lamps according to various embodiments of the present inventive concepts, respectively.

Referring to FIG. 12, an LED lamp 2000 according to some embodiments may include a lamp cover 2420 having a long bar shape in one direction, a plurality of LED modules 200 disposed in the lamp cover 2420, and a pair of sockets 2470a and 2470b disposed at both ends of the lamp cover 2420.

In some embodiments, the plurality of LED modules 200 may be illustrated by four LED modules. The two LED modules 200 may be arranged in series by two, and these two rows may be arranged in parallel. The two rows of LED modules 200 connected in parallel may be arranged such that the front light L1 having a large light emission amount may be emitted through both opposite sides. The first and second wires 2450a and 2450b connected to both ends of the four LED modules 200 may be connected to a pair of sockets 2470a and 2470b, respectively.

Referring to FIG. 13, an LED lamp 2000′ according to some embodiments may include a lamp cover 2420, but include one socket 2700 similarly to the previous embodiment. In addition, the LED lamp 2000′ according to some embodiments may include three LED modules 200 connected in series.

The socket 2700 employed in some embodiments, different from the lamp according to the previous embodiment, may include connection terminals having two polarities, and may be connected to first and second wires 2450a′ and 2450b′, respectively.

According to the above-described embodiment, the flexible substrate having the transmittance rate of 90% or more in the main luminescent region was used to provide an LED module having flexibility and an LED lamp having the same, which may be employed in a device having various design, while reducing a deviation in amounts of light from the front surface and the rear surface, that is, on both surfaces.

The various and advantageous advantages and effects of the present inventive concepts are not limited to the above description, and may be more easily understood in the course of describing a specific embodiment of the present inventive concepts.

While example embodiments have been shown and described above, it will be apparent to those skilled in the art that modifications and variations could be made without departing from the scope of the present inventive concepts as defined by the appended claims.

What may be claimed is:

1. A light emitting diode (LED) module comprising:
a flexible substrate having a first surface on which a circuit pattern is disposed and a second surface opposing the first surface, and having a light transmittance of 80% or more;
a plurality of LED chips on the first surface of the flexible substrate and electrically connected to the circuit pattern;
first and second connection terminals at both ends of the flexible substrate and connected to the circuit pattern; and
a wavelength converter covering the plurality of LED chips, and surrounding the flexible substrate.

2. The LED module according to claim 1, wherein the flexible substrate comprises a material selected from the group consisting of polyimide (PI), polyamide imide (PAI), polyethylene terephthalate (PET), polyethylene naphthalene (PEN) and silicone.

3. The LED module according to claim 1, wherein the flexible substrate has a light transmittance of 90% or more.

4. The LED module according to claim 1, wherein the flexible substrate comprises a colorless polyimide.

5. The LED module according to claim 1, wherein the flexible substrate has a bar shape, and wherein the plurality of LED chips are arranged along a longitudinal direction of the flexible substrate.

6. The LED module according to claim 1, wherein an area forming the circuit pattern is in the range of 1% to 60% of an area of the first surface of the flexible substrate.

7. The LED module according to claim 1, further comprising a white coating layer in an area of the circuit pattern, which is not connected to the plurality of LED chips.

8. The LED module according to claim 1, wherein the wavelength converter includes a transparent resin containing at least one wavelength converting material.

9. The LED module according to claim 8, wherein the wavelength converter includes a first wavelength converter on the first surface of the flexible substrate, and a second wavelength converter on the second surface of the flexible substrate, and wherein a content ratio of the wavelength converting material in the first wavelength converter is greater than a content ratio of the wavelength converting material in the second wavelength converter.

10. The LED module according to claim 8, wherein the wavelength converter includes a first wavelength converter on the first surface of the flexible substrate, and a second wavelength converter on the second surface of the flexible substrate, and wherein a thickness of the first wavelength converter is greater than a thickness of the second wavelength converter.

11. The LED module according to claim 8, wherein the plurality of LED chips are blue LED chips, and the at least one wavelength converting material comprises a green fluorescent material and a red fluorescent material.

12. A light emitting diode (LED) module comprising:
a flexible substrate having first and second surfaces opposing each other, and having a light transmittance of 80% or more and a bar shape;
a circuit pattern on at least the first surface of the flexible substrate;
a plurality of LED chips on the first surface of the flexible substrate in the longitudinal direction of the flexible substrate and electrically connected to the circuit pattern;
first and second connection terminals at both ends of the flexible substrate, and connected to the circuit pattern; and
a wavelength converter including a transparent resin containing at least one wavelength converting material, and having a first wavelength converter on the first surface of the flexible substrate, and a second wavelength converter on the second surface of the flexible substrate.

13. The LED module according to claim 12, wherein the flexible substrate is a colorless polyimide having a light transmittance of 90% or more.

14. The LED module according to claim 12, wherein an area forming the circuit pattern is in the range of 1% to 60% of an area of the first surface of the flexible substrate.

15. The LED module according to claim 12, wherein a content ratio of the wavelength converting material in the first wavelength converter is greater than a content ratio of the wavelength converting material in the second wavelength converter.

16. The LED module according to claim 12, wherein a thickness of the first wavelength converter is greater than a thickness of the second wavelength converter.

17. A light emitting diode (LED) lamp comprising:
a base;
a lamp cover on the base and having an internal space; and
at least one LED module in the internal space of the lamp cover,
wherein the at least one LED module comprises:
a flexible substrate having a first surface on which a circuit pattern is disposed and a second surface opposing the first surface, and having a light transmittance of 80% or more;
a plurality of LED chips on the first surface of the flexible substrate, and electrically connected to the circuit pattern;
first and second connection terminals at both ends of the flexible substrate and connected to the circuit pattern; and
a wavelength converter covering the plurality of LED chips and surrounding the flexible substrate.

18. The LED lamp according to claim 17, wherein the at least one LED module having at least one region thereof bent.

19. The LED lamp according to claim 17, further comprising
a support at a central axis of the internal space and having one end on the base,
a connection frame on the other end of the support; and
an electrode frame on the support,
wherein the at least one LED module comprises a plurality of LED modules, and
wherein the first and second connection terminals of the plurality of LED modules are connected to the connection frame and the electrode frame, respectively.

20. The LED lamp according to claim 19, wherein the plurality of LED modules are arranged radially such that the first surface of each LED module is adjacent to the lamp cover.
